(19) United States
(12) Patent Application Publication
(10) Pub. No.: US 2025/0330148 A1
(43) Pub. Date: Oct. 23, 2025

(54) PIEZOELECTRIC BOUNDARY ACOUSTIC WAVE DEVICE WITH A LAYERED SUBSTRATE

(71) Applicant: Qorvo US, Inc., Greensboro, NC (US)

(72) Inventor: Marc Solal, Longwood, FL (US)

(21) Appl. No.: 19/088,731

(22) Filed: Mar. 24, 2025

Related U.S. Application Data
(60) Provisional application No. 63/637,101, filed on Apr. 22, 2024.

(51) Int. Cl. H03H 9/25; H03H 3/08; H03H 9/02; H03H 9/145

(52) U.S. Cl. CPC H03H 9/25; H03H 3/08; H03H 9/02559; H03H 9/02952; H03H 9/145

(57) ABSTRACT

A piezoelectric boundary acoustic wave (PBAW) device includes a substrate, a piezoelectric film on the substrate, an interdigital transducer on the piezoelectric film, and an overcoat layer on the piezoelectric film. The electrodes of the interdigital transducer are embedded in the overcoat layer. The interdigital transducer has electrodes arranged with an electrode period, and a thickness of the overcoat layer being larger than twice the electrode period.

### CROSS REFERENCE TO RELATED APPLICATION

This application claims priority to U.S. Patent Application No. 63/637,101, filed Apr. 22, 2024, which is incorporated by reference herein in its entirety.

### FIELD OF THE DISCLOSURE

The technology disclosed herein relates generally to piezoelectric boundary acoustic wave (PBAW) devices, also called PBAW filters, and more particularly to PBAW devices with a layered substrate for application in radio frequency (RF) filtering for wireless communications.

### BACKGROUND

Acoustic wave devices are widely used in modern electronics. At a high level, acoustic wave devices include a piezoelectric material in contact with one or more electrodes. Piezoelectric materials acquire a charge when compressed, twisted, or distorted, and similarly compress, twist, or distort when a charge is applied to them. Accordingly, when an alternating electrical signal is applied to the one or more electrodes in contact with the piezoelectric material, a corresponding mechanical signal (i.e., an oscillation or vibration) is transduced therein. Based on the characteristics of the one or more electrodes on the piezoelectric material, the properties of the piezoelectric material, and other factors such as the shape of the acoustic wave device and other structures provided on the device, the mechanical signal transduced in the piezoelectric material exhibits a frequency dependence on the alternating electrical signal. Acoustic wave devices leverage this frequency dependence to provide one or more functions.

Exemplary acoustic wave devices include surface acoustic wave (SAW) filters. In the context of SAW filters, an electrode pitch of an interdigital transducer (IDT) primarily defines a center frequency of the resonators. One issue for SAW filters is the need to use a package with a cavity. This results in an increased device size. The escalating demands of modern RF communication systems necessitate that acoustic wave devices offer increasingly compact form factors. An approach to solve this issue is boundary wave devices. Example boundary wave devices include piezoelectric boundary acoustic wave (PBAW) devices. PBAW devices add an overlaying layer made of a fast material on top of an IDT on a piezoelectric substrate. Such a structure suppresses the need for a cavity package. In recent years, PBAW devices have been successfully used in wireless communication systems as a result of their small size and low insertion loss provided by resonator-type structures, built on piezoelectric substrates with high electromechanical coupling factors.

Yet, conventional PBAW devices have reached a development bottleneck. Due to the overlaying layer made of a fast material, the resonance frequency of the PBAW devices may be pushed above the substrate cutoff frequency, resulting in bulk radiation losses. One approach is to increase a thickness of an IDT to push the resonance frequency down. However, with advance technology nodes in the sub-micron era, it has become quite challenging to manufacture an IDT with an ever-decreasing Critical Dimension (CD) for an electrode width while maintaining a large electrode thickness. Consequently, this opens up opportunities for innovative approaches in the realm of PBAW devices beyond the conventional PBAW devices.

### SUMMARY

Example aspects of the present disclosure provide solutions that allow to make acoustic wave filters without a cavity package by using boundary waves and to maintain low losses. Without the need for a cavity package, the size of the acoustic wave filters can be reduced. Also, this technology allows in principle to stack several dies to reduce the size even more. Some exemplary acoustic wave filters include an IDT disposed on a layered substrate and covered with an acoustically fast material to avoid using a cavity package. The layered substrate includes a piezoelectric layer on top of a faster substrate. Intermediary layers may be disposed between the piezoelectric layer and the faster substrate.

In one embodiment, a piezoelectric boundary acoustic wave (PBAW) device includes a substrate, a piezoelectric film on the substrate, an interdigital transducer on the piezoelectric film, the interdigital transducer having electrodes arranged with an electrode period, and an overcoat layer on the piezoelectric film, the electrodes of the interdigital transducer being embedded in the overcoat layer, a thickness of the overcoat layer being larger than twice the electrode period. In some instances, the substrate has a shear velocity faster than 4000 m/s. In some instances, the substrate is made of a material selected from silicon, quartz, silicon carbide, or sapphire. In some instances, the electrodes are embedded in the piezoelectric film. In some instances, the PBAW device further includes one or more material layers disposed between the substrate and the piezoelectric film. In some instance, the PBAW device further includes a dielectric film disposed between the substrate and the piezoelectric film. In some instances, the dielectric film is made of silicon oxide. In some instances, the substrate is a semiconductor substrate with a trap-rich band. In some instances, the thickness of the overcoat layer is larger than three times the electrode period. In some instances, the thickness of the overcoat layer is larger than four times the electrode period. In some instances, the PBAW device is free of a cavity directly above the interdigital transducer. In some instances, the overcoat layer includes an embedding layer on the piezoelectric film and an overlaying layer on the embedding layer. The electrodes of the interdigital transducer are embedded in the embedding layer, and a thickness of the overlaying layer is larger than twice the electrode period. In some instances, the embedding layer is made of silicon oxide. In some instances, the overlaying layer is made of a material selected from aluminum nitride, silicon nitride, aluminum oxide, silicon, silicon carbide, or diamond. In some instances, the piezoelectric film is made of lithium tantalate or lithium niobate. In some instances, a thickness of the piezoelectric film is thinner than the electrode period. In some instances, the piezoelectric film is made of a Y-rotated, X-propagating lithium niobate with an orientation between Y and Y+50°. In some instances, the piezoelectric film is made of a Y-rotated, X-propagating lithium niobate with an orientation between Y+115° and Y+130°. In some instances, another die is stacked atop the overcoat layer. In some instances, the overcoat layer has a same material as the substrate, and the another die is a second PBAW stacked atop the PBA W.

In another embodiment, a method of fabricating a PBAW device includes forming a layered substrate, the layered substrate including a substrate and a piezoelectric film on the substrate, a shear wave velocity of the substrate being larger than that of the piezoelectric film, forming interdigital transducer on the piezoelectric film, forming a dielectric layer coating the interdigital transducer, and depositing an overlaying layer on the dielectric layer, a shear wave velocity of the overlaying layer being larger than that of the dielectric layer. In some instances, the piezoelectric film is obtained by wafer bonding and polishing. In some instances, the piezoelectric film is obtained by implanting ions on a piezoelectric wafer, bonding the piezoelectric wafer on a substrate wafer, splitting the piezoelectric wafer to form an initial piezoelectric film, and polishing the initial piezoelectric film. In some instances, the forming of the layered substrate includes forming a trap-rich band in a top portion of the substrate. In some instances, the forming of the layered substrate includes forming an intermediary dielectric layer between the substrate and the piezoelectric film. In some instances, the overlaying layer is made by bonding a wafer on top of the embedding layer.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description, serve to explain the principles of the disclosure.

FIGS. 1A and 1B illustrate perspective and cross-sectional views of a conventional boundary acoustic wave device.

FIG. 2 illustrates the concept of Euler angles and how they describe the crystalline orientation of a material layer, according to some aspects of the present disclosure.

FIG. 3 illustrates distribution of displacements of boundary acoustic waves of a boundary acoustic wave device, according to some aspects of the present disclosure.

FIGS. 4, 5, and 6 illustrate cross-sectional views of various embodiments of exemplary boundary wave devices, according to some aspects of the present disclosure.

FIGS. 7A, 7B, 7C, and 7D illustrate simulated performance of exemplary boundary wave devices, according to some aspects of the present disclosure.

FIG. 8 illustrates an equivalent circuit of an exemplary boundary wave device, according to some aspects of the present disclosure.

FIG. 9 illustrates a block diagram of an exemplary wireless communication device, according to some aspects of the present disclosure.

FIG. 10 illustrates a method of manufacturing a boundary acoustic wave device, according to various embodiments of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Small surface acoustic wave (SAW) filters have been strongly needed in a radio frequency (RF) filter for an RF communication system. In order to meet this requirement, SAW filters may use chip size package (CSP) technology. However, cavity formation is required on the surface of chips, where SAW propagates, restricting the miniaturization of SAW filters. On the other hand, a boundary acoustic wave device in which elastic wave energy concentrates near the boundary does not require cavity formation. Thus, it is expected that a device using boundary acoustic wave will realize a simple package structure with a small form factor. A device using boundary acoustic wave can be made by inserting an interdigital transducer (IDT) at the interface (boundary) between a piezoelectric material and another material. The other material can be a different piezoelectric material or other than a piezoelectric material, such as a dielectric material. With the piezoelectric material in forming on side of the boundary, such a device is referred to as a piezoelectric boundary acoustic wave (PBAW) device.

The Stoneley wave and shear-horizontal (SH) type boundary acoustic wave are known as boundary acoustic waves. The Stoneley wave mainly consists of a longitudinal wave (P) and a shear vertical wave (SV) components. The SH-type boundary acoustic wave mainly consists of an SH component. Usually, the electromechanical coupling coefficient k², which characterizes the ability to realize wide relative bandwidths, is larger for SH-type boundary waves.

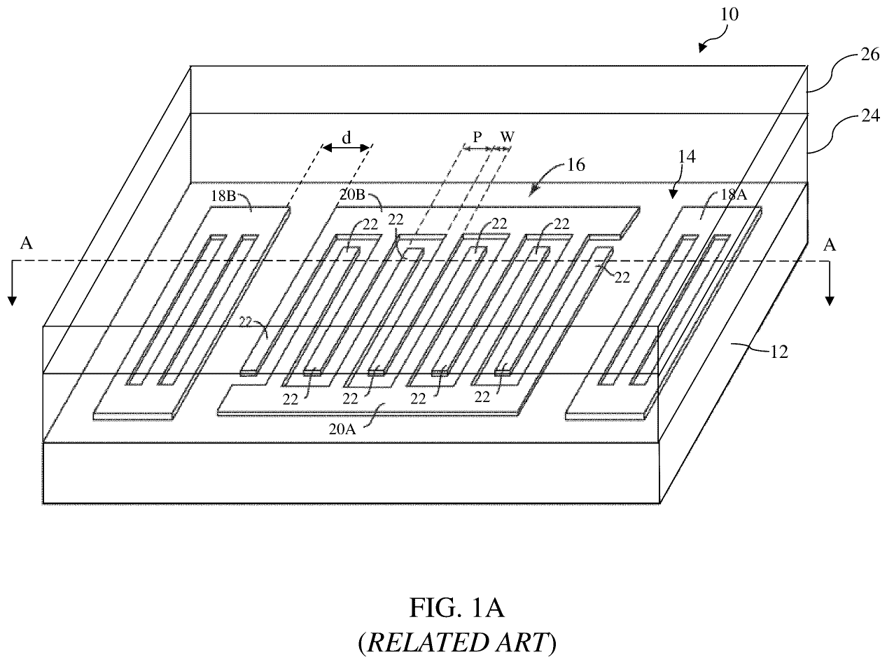

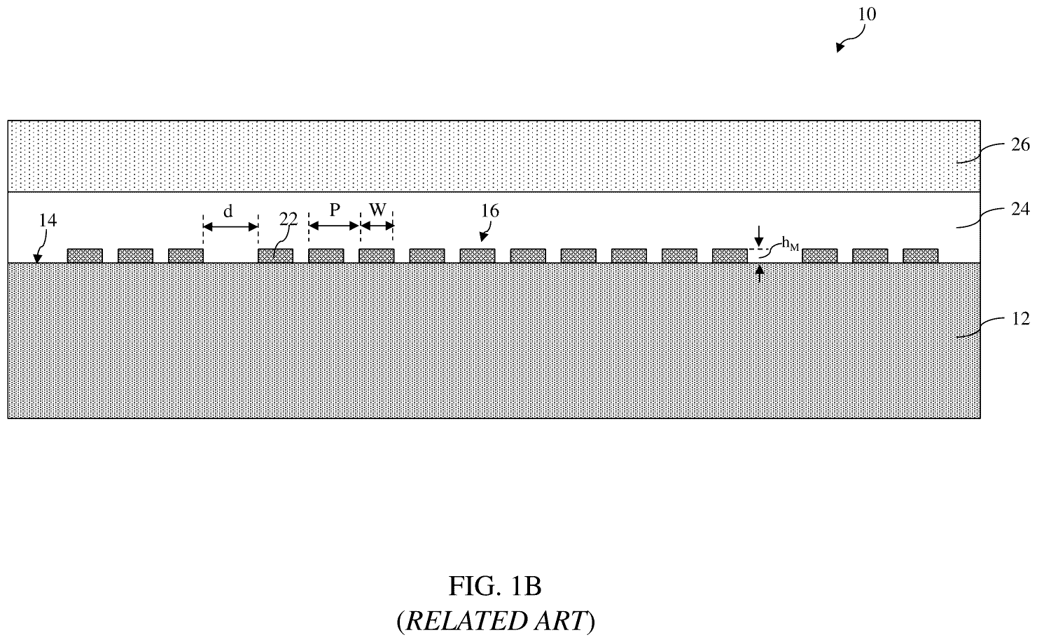

Before addressing exemplary aspects of the present disclosure, a brief discussion of a conventional approach to a PBAW device and its limitations is provided with reference to FIGS. 1A and 1B.

FIG. 1A shows a perspective view of a conventional PBAW device 10. FIG. 1B shows a cross-sectional view of the PBAW device 10 cut along the A-A line in FIG. 1A. Referring to FIGS. 1A and 1B collectively, the PBAW device 10 may comprise a piezoelectric substrate 12 for providing a propagation of an acoustic wave. In some embodiments, the piezoelectric substrate 12 is a single crystal piezoelectric substrate. In furtherance of some embodiments, the piezoelectric substrate 12 is a single crystal lithium niobate (LN) substrate or a single crystal lithium tantalate (LT) substrate.

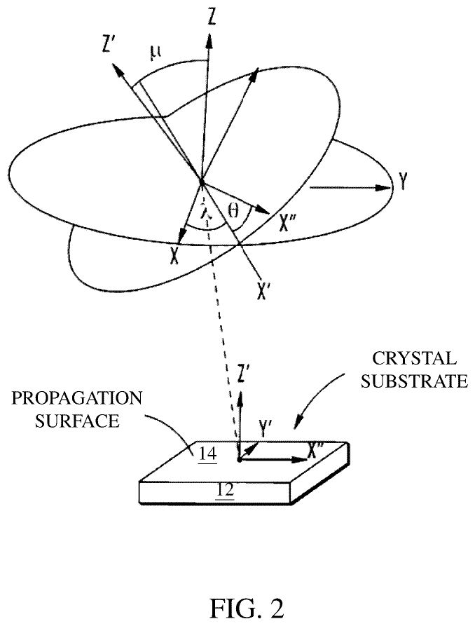

In some embodiments, the piezoelectric substrate 12 may be Y-rotated. FIG. 2 depicts an example of Euler angles (λ, μ, θ) that may provide reference for the Y-rotation. In these embodiments, the shear wave may propagate in the X-direction. The piezoelectric substrate 12 may in some embodiments be referred to as a Y-rotated, X-propagating lithium niobate (YX-LN) substrate or a Y-rotated, X-propagating lithium tantalate (YX-LT) substrate. For example, regarding a YX-LN substrate or a YX-LT substrate, Y+18° denotes a 18° Y-rotation. Since the Euler angle μ defines the rotation from a plane with normal Z while Y+α defines a rotation from a plane with Y normal, the angle μ is related to a by the relation μ=α−90°. For a propagation along X axis, the other Euler angle λ and θ are 0.

Still referring to FIGS. 1A and 1B, an interdigital transducer (IDT) 16 is disposed on the top surface 14 of the piezoelectric substrate 12. A first reflector structure 18A is disposed on the top surface 14 of the piezoelectric substrate 12 adjacent to the IDT 16 with a separation d, and a second reflector structure 18B is disposed on the top surface 14 of the piezoelectric substrate 12 adjacent to the IDT 16 opposite the first reflector structure 18A with a separation d′ where d′ is often equal to d. In some embodiments, the reflector structures 18A and 18B are omitted in the PBAW device 10. The IDT 16 and the reflector structures 18A and 18B (if present) may be made of copper (Cu), gold (Au), tungsten (W), platinum (Pt), aluminum (Al), titanium (Ti) or other suitable metal or metal alloy. It may use multilayer metallic electrodes to simplify the fabrication process, to improve the power durability and/or to combine the material properties (for example high density low conductivity tungsten or platinum with low density high conductivity aluminum). In practical devices, the period P, the electrode width W may vary along the device, but this variation is normally small and can be neglected when considering the guiding or not of the modes.

The IDT 16 includes a first comb electrode 20A and a second comb electrode 20B, each of which includes a number of electrode fingers 22 that are interleaved with one another as shown. The electrode fingers 22 have an electrode height (thickness) h_{M}. A lateral distance between adjacent electrode fingers 22 of the first comb electrode 20A and the second comb electrode 20B defines an electrode period (or referred to as electrode pitch) P of the IDT 16. A finger width W of the adjacent electrode fingers 22 over the electrode period P may define a metallization ratio (or referred to as duty factor) M of the IDT 16, which may dictate certain operating characteristics of the PBAW device 10. In some embodiments, the separation d is larger than the electrode pitch P. In some embodiments, the separation d is close to the separation between consecutive electrodes in the IDT (d≈P−W).

The IDT 16 is embedded in an embedding layer 24. The embedding layer 24 may have a positive temperature coefficient of frequency (TCF). In some embodiments, the embedding layer 24 is a silicon oxide (SiO₂) layer. In other embodiments, the embedding layer 24 may be some other dielectric material.

In some embodiments, the PBAW device 10 may further include an additional material 26 overlaying the embedding layer 24. The additional material 26 may also be referred to as an overlaying layer 26. In some embodiments, the overlaying layer 26 may be made of silicon oxide (SiO₂), silicon nitride (Si₃N₄), aluminum nitride (AlN), aluminum oxide (AlO) and/or some other material. The overlaying layer 26 may be specifically chosen to have an acoustic velocity greater than that of the embedding layer 24. By having a greater acoustic velocity than the embedding layer 24, acoustic motion on a top surface of the overlaying layer 26 may be suppressed. In embodiments, the overlaying layer 26 may be flat, as depicted in FIG. 1B, while in other embodiments the overlaying layer 26 may be some other shape such as rounded. It is also possible to stack another die on top of the overlaying layer.

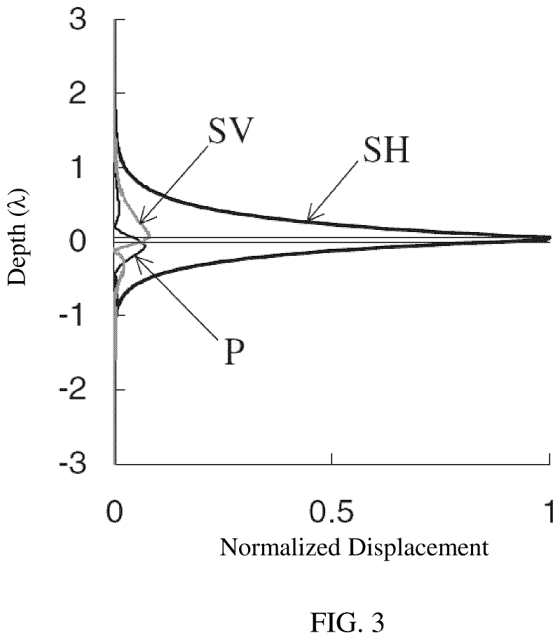

In operation, an alternating electrical input voltage provided between the first comb electrode 20A and the second comb electrode 20B is transduced into a mechanical signal in the piezoelectric substrate 12, resulting in one or more acoustic waves therein. In the case of the PBAW device, depending on the substate orientation, the resulting acoustic waves may be mostly a shear-horizontal (SH) type boundary acoustic wave. For example, FIG. 3 shows the calculated displacement for a wave propagating at the interface between a piezoelectric substrate 12 of lithium niobate (LN) and an embedding layer 24 of silicon oxide (SiO₂). An IDT 16 made of a uniform gold film with a thickness of 0.06λ is present at the interface. The propagating mode is predominately in a shear horizontal mode, and the displacement becomes almost zero when the distance from the interface is larger than about two wavelengths. This means that if an overlaying layer 26 thicker than two wavelengths is present, a cavity package is not needed. Normally, for a PBAW device to function properly, its resonance frequency should be below the cut-off frequencies for the piezoelectric substrate and for the overlaying layer. This ensures that the boundary acoustic wave profile is evanescent both in the piezoelectric substrate and in the overlaying layer.

The electrode period P of the IDT 16 may at least partially define a wavelength 2 at a resonance frequency fₛ of the PBAW device 10. For a single electrode IDT 16 such as the one shown in FIGS. 1A and 1B, at the resonance frequency fₛ, the wavelength λ is about twice the electrode period P (λ=2P). In other words, if sₓ is the wave slowness in the propagation direction along X-axis and fₛ is the resonance frequency, there is

$$\frac{1}{{s}_{x} {f}_{s}} = 2 p or {s}_{x} = \frac{1}{2 p {f}_{s}}$$

For the boundary acoustic wave to be evanescent in the vertical direction, the slowness sₓ must be large enough for the slownesses of all the modes in the vertical direction to be imaginary. Assuming regular convex slowness curves, this means in general that:

$${s}_{x} > {s}_{substrate} and {s}_{x} > {s}_{overlay}$$

where s_{substrate} and s_{overlay} are the slowness of the slowest wave in the overlaying layer and in the substrate. This is a typical guiding situation similar to what is seen on guided modes resonator (LRT) for which the resonance frequency has to be lower than the cutoff frequency of the substrate. If the equation is expressed in term of frequency, there is

$${f}_{s} < \frac{{v}_{OVERLAY}}{2 p} and {f}_{s} < \frac{{v}_{SUBSTRATE}}{2 p}$$

which shows that the resonance frequency fₛ needs to be lower than the two cutoff frequencies. These conditions can be met by using a fast overlaying layer. If the overlaying layer is not fast enough (e.g., silicon oxide), another approach consists in reducing the resonance frequency by using thicker and/or heavier metal in the thickness h_{M} of the electrodes of the IDT 16. For example, gold electrodes may be used other than copper. If the resonance is above the cutoff frequencies, some energy is dissipated in the substrate and/or the overlaying layer. This means that the top of the overlaying layer would have some acoustic displacement and it is not isolated. Some energy may be lost in the substrate and/or the overlaying layer. This may give a rise to losses and/or undesired modes.

The table below gives a list of materials and their acoustic velocities ordered according to their shear velocities.

| Material | Shear (m/s) | Longitudinal (m/s) |
|---|---|---|
| Aluminum | 3110 | 6422 |
| Silicon oxide | 3696 | 6035 |
| Lithium niobate | 3474/4043 | 6544 |
| (X propagation) | | |
| Silicon nitride | 5467 | 8759 |
| Aluminum nitride | 5809 | 10287 |

Taking lithium niobate as an example, for a propagation along X-axis the two shear modes have a velocity of 3474 m/s and 4043 m/s, respectively. If the crystal orientation is about Y-axis, then the shear horizontal mode is at 4043 m/s. The velocity of the shear mode in silicon oxide is between these two numbers, while it is larger for silicon nitride, aluminum nitride, and silicon. According to the discussion above, when a silicon oxide overlaying layer is used, the metal thickness h_{M} of the electrodes needs to be large enough to have a resonance frequency significantly lower than 3696/(2p) to avoid buck radiation. An alternative solution is to use heavy metals for the IDT, which increases material cost and manufacturing complexity. There are some advantages to choosing a fast material for the overlaying layer, such as an aluminum nitride overlaying layer. For the thinner electrodes, the lithium niobate bulk cutoff frequency may be between the resonance and antiresonance frequencies. This is due to the presence of the fast overlaying layer which pushes the resonance frequency up. If a slower overlaying layer, like silicon oxide or aluminum, is used, then the overlay cutoff frequency is lower and thick and/or dense electrodes are also necessary to avoid bulk radiation. This results in a smaller period for a given resonance frequency. For low frequency filters, this is an advantage because the result is a smaller die. When the goal is to design higher frequency filters, the electrode width becomes too narrow, and it has become quite challenging to manufacture an IDT with a large metal thickness.

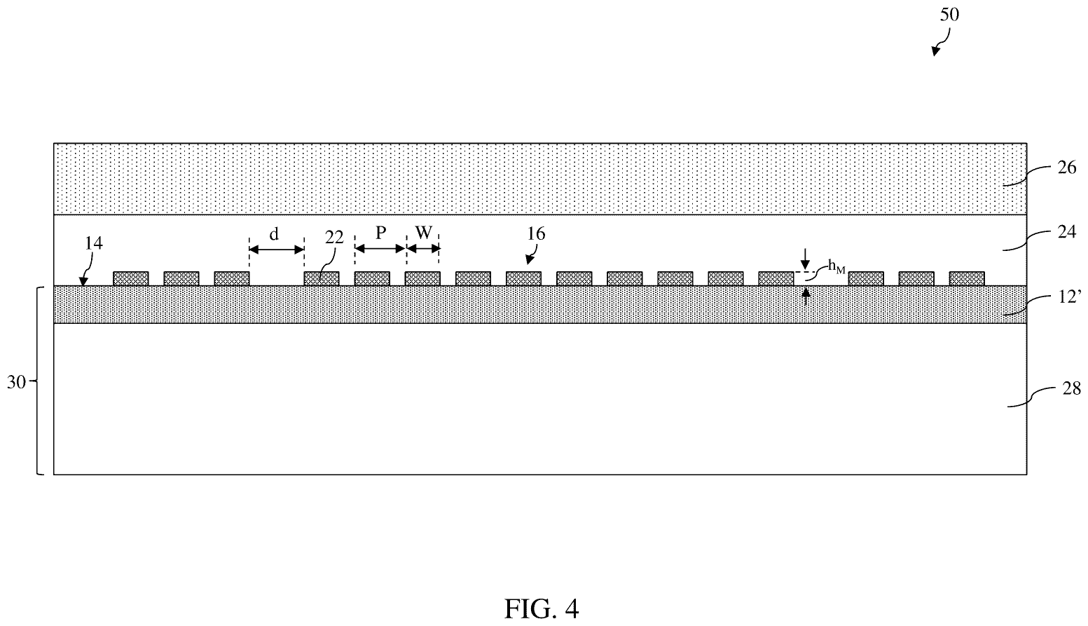

Reference is now made to FIG. 4, which illustrates an example of a PBAW device 50 that eases the need to manufacture thick electrodes for high frequency filters. Compared to FIG. 1B, the piezoelectric substrate 12 in the PBAW device 10 is replaced with a layered substrate 30 in the PBAW device 50. The layered substrate 30 includes a piezoelectric film (or a piezoelectric layer) 12′ bonded or deposited on a substrate 28 that is made of a material faster than the piezoelectric material. The fast substrate 28 has a higher bulk cutoff frequency that avoids the bulk radiation. To achieve this, the fast substrate 28 has a shear velocity faster than about 4000 m/s. In some embodiments, the fast substrate 28 is made of a fast material selected from silicon, quartz, silicon carbide, or sapphire. In one example, the fast substrate 28 is a single crystal silicon substrate with a (100) crystalline orientation. In another example, the fast substrate 28 is a single crystal silicon substrate with a (110) crystalline orientation. With different crystalline orientation, the acoustic wave velocity is different. Thus, the crystalline orientation of the fast substrate 28 can be selected upon device performance needs.

The piezoelectric film 12′ may be made of lithium niobate (LN) or lithium tantalate (LT). In some embodiments, the piezoelectric film 12′ has an orientation between Y and Y+50°. In some other embodiments, the piezoelectric film 12′ has an orientation between Y+115° and Y+130°. In one instance, the piezoelectric film 12′ has an orientation between Y+115° and Y+125°. A thickness of the piezoelectric film 12′ may be less than one electrode period P. In some embodiments, the piezoelectric film 12′ may be formed by wafer bonding and polishing. In furtherance of some embodiments, the piezoelectric film 12′ may be formed by implanting ions on a piezoelectric wafer, bonding the wafer on the wafer of the fast substrate 28, splitting the piezoelectric wafer to get the initial piezoelectric film, and polishing the initial piezoelectric film.

The embedding layer 24 and the overlaying layer 26 collectively overcoat the piezoelectric film 12′ and may be collectively referred to as an overcoat layer. The IDT 16 is embedded in the embedding layer 24. In some embodiments, the embedding layer 24 is made of silicon oxide (SiO₂). The overlaying layer 26 is disposed on the embedding layer 24. In the depicted embodiment as shown in FIG. 4, the bottom surfaces of the IDT 16 are coplanar with the top surface of the piezoelectric film 12′. In some alternative embodiments, bottom portions of the IDT 16 may further be embedded in the piezoelectric film 12′. The overlaying layer 26 has an acoustic velocity faster than the embedding layer 24. In some embodiments, the overlaying layer 26 is made of a material selected from aluminum nitride, silicon nitride, aluminum oxide, silicon, silicon carbide, or diamond. To suppress the bulk radiation, a thickness of the overlaying layer 26 may be greater than 2 electrode periods P, in some embodiments. With this thickness, the displacement becomes almost zero, and there is no need for a cavity to present on top of the IDT 16. In furtherance of some embodiments, a thickness of the overlaying layer 26 may be greater than 3 times the electrode period P or even 4 times the electrode period P. The overlaying layer may be made by deposition, but also can be made by bonding a wafer on top of the embedding layer. In this case, to avoid thermal expansion issues, a good choice for the overlaying material is to use the same material as the substrate. In some embodiments, the embedding layer 24 and the overlaying layer 26 are the same layer, such that the overcoat layer is one continuous layer (e.g., the overlaying layer 26).

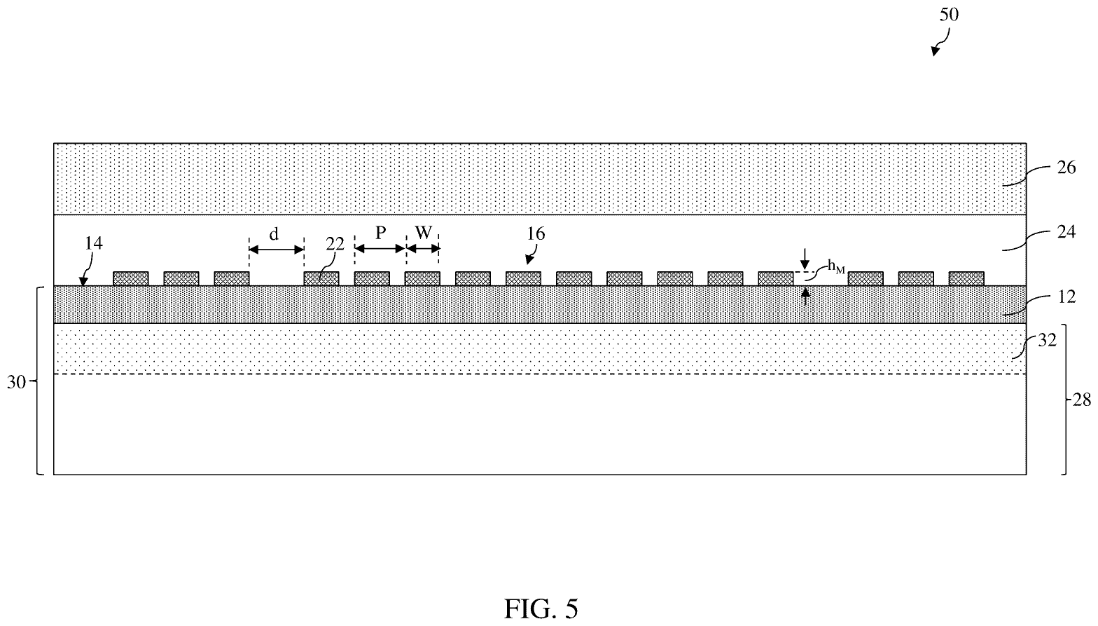

Referring to FIG. 5, if the fast substrate 28 is a semiconductor substrate, such as a silicon substrate, the fast substrate 28 may receive an implantation process to form a trap-rich layer 32 in a top portion of the fast substrate 28. The trap-rich layer 32 “freezes” the excess of carriers attracted at the top of the fast substrate 28, which improves PBAW device performance. Other than the implantation process, the trap-rich layer 32 may be alternatively formed by depositing a polysilicon layer on the top of the fast substrate 28. If the overlaying material is a semiconductor material bonded on the device, the same type of process may be used for this layer.

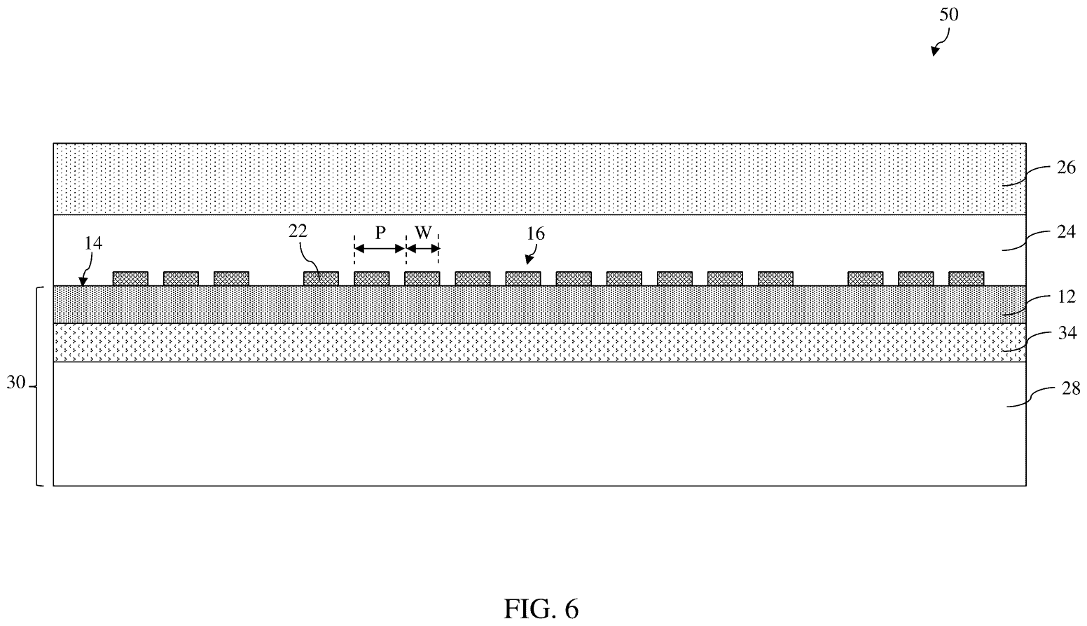

Referring to FIG. 6, an intermediary layer 34 may be deposited between the piezoelectric film 12′ and the fast substrate 28. In some embodiments, the intermediary layer 34 is made of silicon oxide (SiO₂). The intermediary layer 34 allows to increase the piezoelectric coupling and improves the temperature coefficient of frequency (TCF). In furtherance of some embodiments, the fast substrate 28 is a semiconductor substrate that further includes a trap-rich layer similar to the fast substrate 28 as depicted in FIG. 5. In furtherance of some embodiments, there are several layers disposed between the piezoelectric film 12′ and the fast substrate 28, such as an intermediary layer 34 disposed under the piezoelectric film 12′ and a polysilicon layer disposed on the top of the fast substrate 28 as a trap-rich layer.

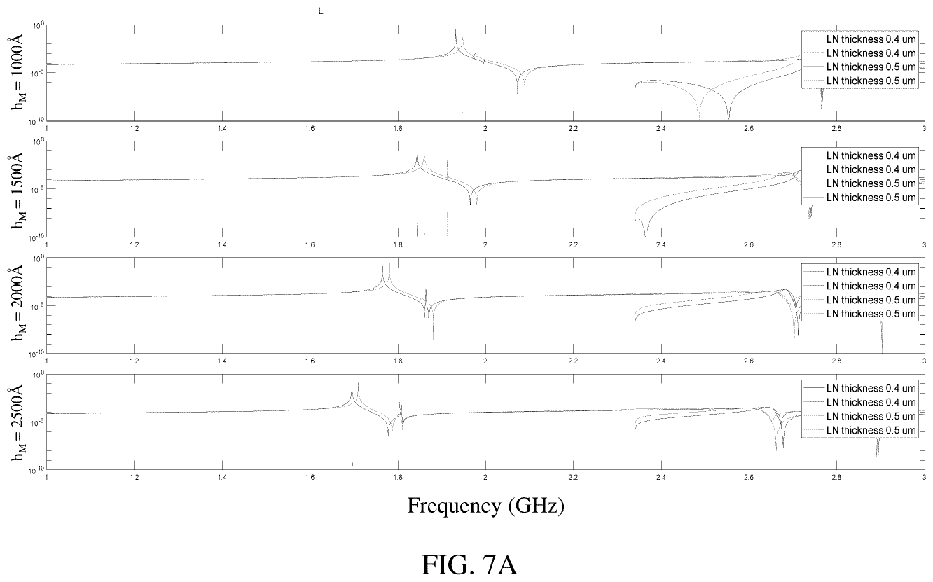

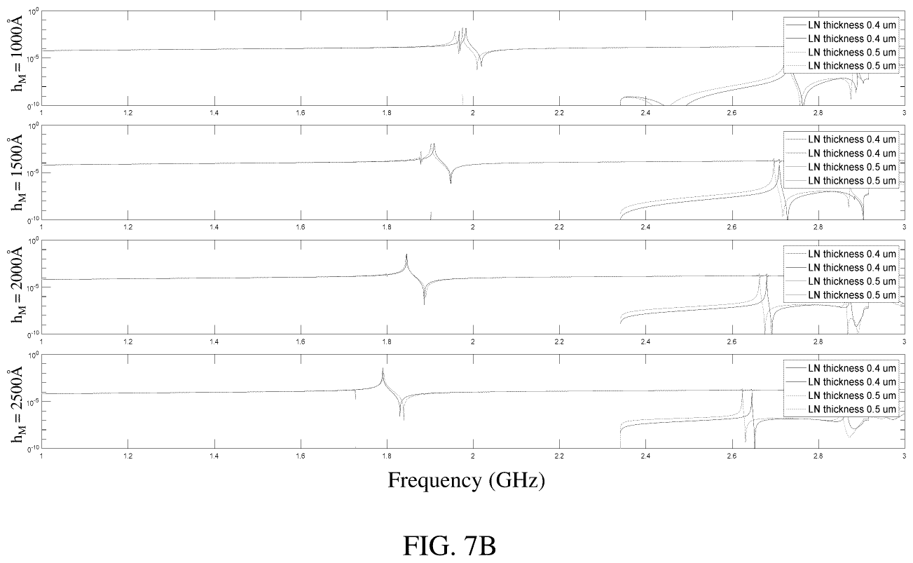

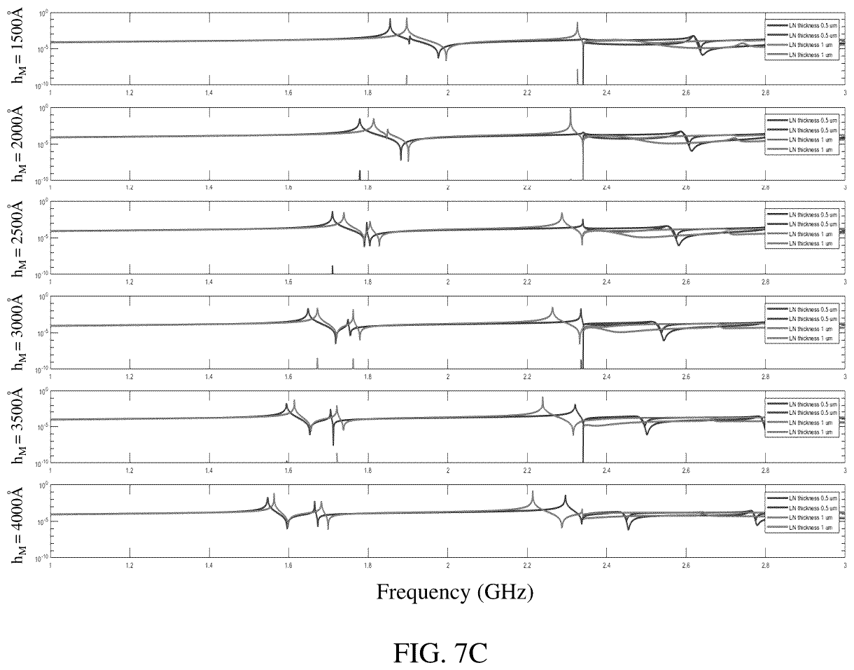

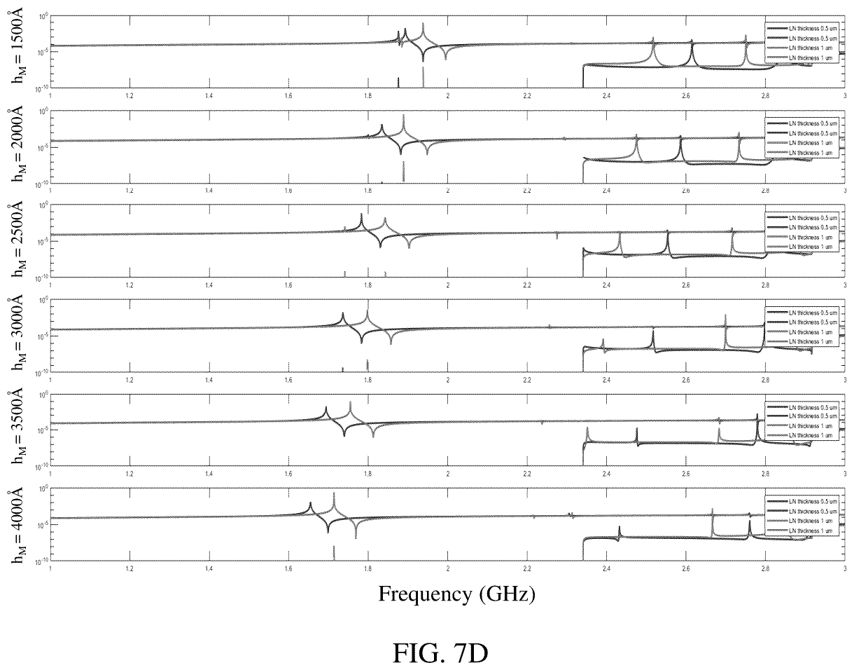

FIG. 7A illustrates periodic FEM/BEM simulation results for an aluminum nitride overlaying layer 26 on top of a layered substrate 30. The figure shows the simulated admittance and conductance for an infinite periodic device. The bulk cut off frequency is shown by the conductance increase at about 2.35 GHz. The electrodes are made of copper with various thickness h_{M} (e.g., 1000 Å, 1500 Å, 2000 Å, 2500 Å). The electrode period P is 1 μm with a duty factor 50%. The fast substrate 28 is a single crystal silicon with (100) crystalline orientation. The piezoelectric film 12′ is a Y+41° LN film. The thickness of the piezoelectric film 12′ is 0.4 or 0.5 μm. There is a 0.5 um silicon oxide layer between the fast substrate 28 and the piezoelectric film 12′. The embedding layer 24 is another 0.5 um silicon oxide layer. Depending on the lithium niobate orientation, the excited mode is shear horizontal. Normally, to suppress the spurious, the orientation and the stack need to be optimized. For a given stack, there may be one orientation in this range without spurious. In the depicted embodiment, the significance of an orientation between Y+0° and Y+50° is that it gives the most coupling and a spurious-free passband. The simulated coupling factor is between 14 and 16%.

FIG. 7B illustrates periodic FEM/BEM simulation results for an aluminum nitride overlaying layer 26 on top of a layered substrate 30. The electrodes are made of copper with various thickness h_{M} (e.g., 1000 Å, 1500 Å, 2000 Å, 2500 Å). The electrode period P is 1 μm with a duty factor 50%. The fast substrate 28 is a single crystal silicon with (100) crystalline orientation. The piezoelectric film 12′ is a Y+120° LN film. The thickness of the piezoelectric film 12′ is 0.4 or 0.5 μm. There is a 0.5 um silicon oxide layer between the fast substrate 28 and the piezoelectric film 12′. The embedding layer 24 is another 0.5 um silicon oxide layer. Depending on the lithium niobate orientation, the excited mode is Stoneley wave. The orientation between Y+115° and Y+130° provides a spurious-free passband, in some embodiments. The simulated coupling factor is between 5 and 6%.

FIG. 7C illustrates periodic FEM/BEM simulation results for a silicon overlaying layer 26 on top of a layered substrate 30. The electrodes are made of copper with various thickness h_{M} (e.g., 1500 Å, 2000 Å, 2500 Å, 3000 Å, 3500 Å, 4000 Å). The electrode period P is 1 μm with a duty factor 50%. The fast substrate 28 is a single crystal silicon with (100) crystalline orientation. The piezoelectric film 12′ is a Y+40° LN film. The thickness of the piezoelectric film 12′ is 0.4 or 0.5 μm. There is a 0.5 um silicon oxide layer between the fast substrate 28 and the piezoelectric film 12′. The embedding layer 24 is another 0.5 um silicon oxide layer. Depending on the lithium niobate orientation, the excited mode is shear horizontal. The orientation between Y+0° and Y+50° gives the most coupling and a spurious-free passband. The simulated coupling factor is between 11 and 14%.

FIG. 7D illustrates periodic FEM/BEM simulation results for a silicon overlaying layer 26 on top of a layered substrate 30. The electrodes are made of copper with various thickness h_{M} (e.g., 1500 Å, 2000 Å, 2500 Å, 3000 Å, 3500 Å, 4000 Å). The electrode period P is 1 μm with a duty factor 50%. The fast substrate 28 is a single crystal silicon with (100) crystalline orientation. The piezoelectric film 12′ is a Y+120° LN film. The thickness of the piezoelectric film 12′ is 0.4 or 0.5 μm. There is a 0.5 um silicon oxide layer between the fast substrate 28 and the piezoelectric film 12′. The embedding layer 24 is another 0.5 um silicon oxide layer. Depending on the lithium niobate orientation, the excited mode is Stoneley wave. The orientation between Y+115° and Y+130° provides a spurious-free passband, in some embodiments. The simulated coupling factor is between 11 and 14%.

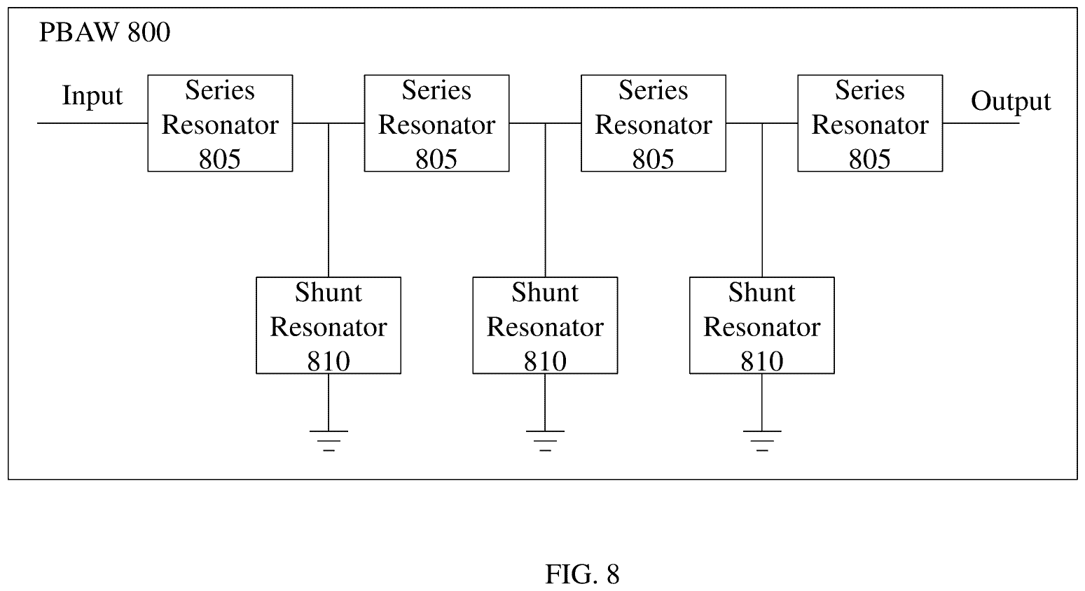

FIG. 8 depicts a high level example of a PBAW device 800, such as the PBAW device 50. In embodiments, the PBAW device 800 may have several resonators such as series resonators 805, which may be similar to resonators 16 of a first type, or shunt resonators 810, which may be similar to resonators 16 of a second type. In general, each of the series resonators 805 may have similar electrode periods and/or frequency features. Similarly, each of the shunt resonators 810 may have similar electrode periods and/or frequency features. Although a certain number and configuration of series resonators 805 and shunt resonators 810 are shown here for PBAW device 800, other embodiments may have different numbers or configurations of series and shunt resonators 805 and 810. In embodiments, each of the resonators may have resonance frequencies, fR, and anti-resonance frequencies, fA. In embodiments, the shunt resonators 810 may all have similar resonance and anti-resonance frequencies to one another, and the series resonators 805 may all have similar resonance and anti-resonance frequencies to one another. In embodiments, the difference between fR and fA of the series resonators may be approximately equal to the difference between fR and fA of the shunt resonators. In some embodiments, fA of the shunt resonators may be approximately equal to fR of the series resonators. The performances may be improved by connecting several reactive elements for example inductances in series or in parallel with one or several resonators. More complex filter topologies may be used as it is well known. Also, all the topologies used for designing SAW or BAW filters or duplexers, not shown in the figures may be used. In particular, coupled resonator filters which involve the acoustic coupling of several transducers between reflectors may be used.

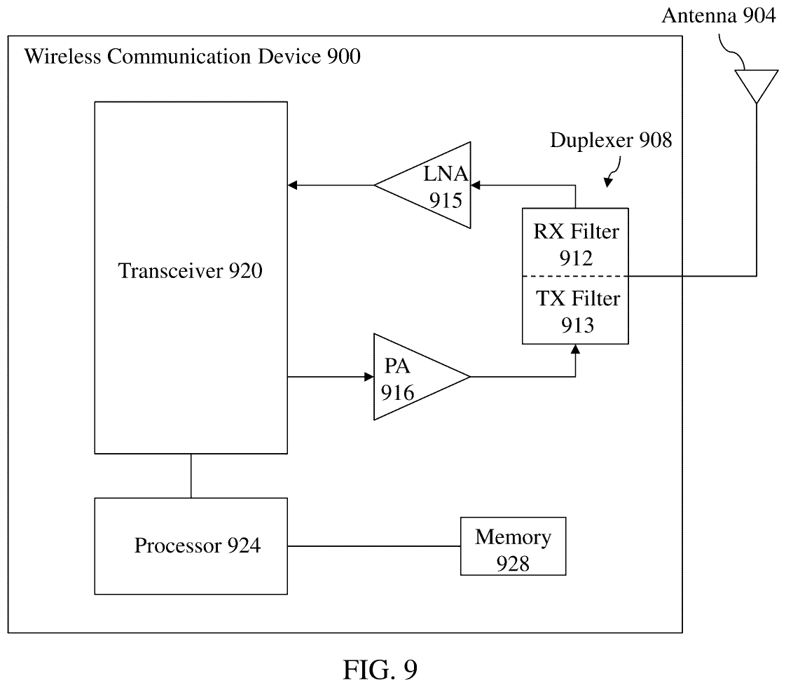

FIG. 9 illustrates a wireless communication device 900, which implements the PBAW device 50 or the PBAW device 800. The wireless communication device 900 may have an antenna structure 904, a duplexer 908 (containing an RX filter 912 and a TX filter 913), a power amplifier (PA) 916, a low noise amplifier (LNA) 915, a transceiver 920, a processor 924, and a memory 928 coupled with each other at least as shown.

The antenna structure 904 may include one or more antennas to transmit and receive radio frequency (RF) signals over the air. The antenna structure 904 may be coupled with the duplexer 908 that operates to selectively couple the antenna structure with the LNA 915 or the PA 916. When transmitting outgoing RF signals, the TX filter 913 may couple the antenna structure 904 with the PA 916. When receiving incoming RF signals, the RX filter 912 may couple the antenna structure 904 with the LNA 915. The RX and TX filters 912 and 913 may include one or more PBAW devices, such as PBAW devices 50 or 800. In some embodiments, the RX and TX filters 912 and 913 may include a first plurality of series resonators and a second plurality resonators. The RX filter 912 may filter the RF signals received from the antenna structure 904 and pass portions of the RF signals within a predetermined bandpass to the transceiver 920.

When transmitting outgoing RF signals, the duplexer 908 may couple the antenna structure 904 with the PA 916. The PA 916 may receive RF signals from the transceiver 920, amplify the RF signals, and provide the RF signals to the antenna structure 904 for over-the-air transmission.

The processor 924 may execute a basic operating system program, stored in the memory 928, in order to control the overall operation of the wireless communication device 900. For example, the processor 924 may control the reception of signals and the transmission of signals by transceiver 920. The processor 924 may be capable of executing other processes and programs resident in the memory 928 and may move data into or out of memory 928, as desired by an executing process.

The transceiver 920 may receive outgoing data (e.g., voice data, web data, e-mail, signaling data, etc.) from the processor 924, may generate RF signals to represent the outgoing data, and provide the RF signals to the PA 916. Conversely, the transceiver 920 may receive RF signals from the filter 912 that represent incoming data. The transceiver 920 may process the RF signals and send incoming signals to the processor 924 for further processing.

In various embodiments, the wireless communication device 900 may be, but is not limited to, a mobile telephone, a paging device, a personal digital assistant, a text-messaging device, a portable computer, a desktop computer, a base station, a subscriber station, an access point, a radar, a satellite communication device, or any other device capable of wirelessly transmitting/receiving RF signals.

Those skilled in the art will recognize that the wireless communication device 900 is given by way of example and that, for simplicity and clarity, only so much of the construction and operation of the wireless communication device 900 as is necessary for an understanding of the embodiments is shown and described. Various embodiments contemplate any suitable component or combination of components performing any suitable tasks in association with wireless communication device 900, according to particular needs. Moreover, it is understood that the wireless communication device 900 should not be construed to limit the types of devices in which embodiments may be implemented.

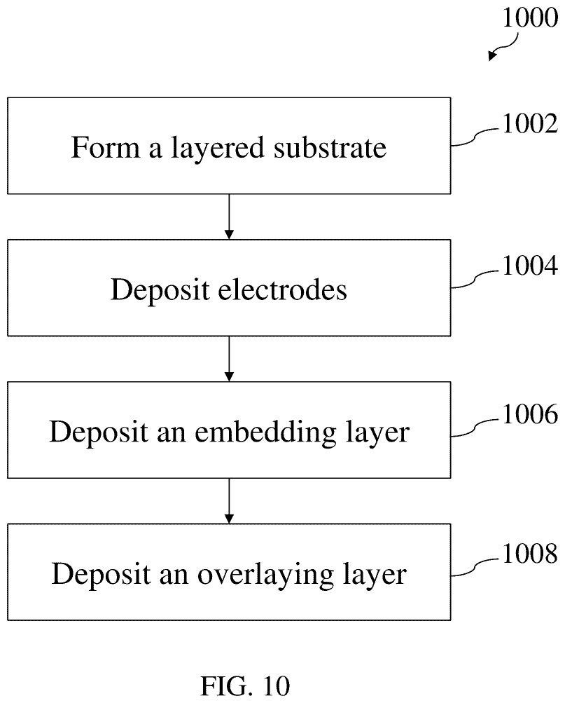

FIG. 10 depicts an example process for constructing a PBAW device such as the PBAW device 50 or the PBAW device 800. Initially, a layered substrate such as the layered substrate 30 may be formed at step 1002. The layered substrate 30 includes a piezoelectric film such as the piezoelectric film 12′ over a fast substrate such as the fast substrate 28. Optionally, the layered substrate 30 also includes one or more intermediary layer such as the intermediary layer 34 disposed between the piezoelectric film and the fast substrate. Next, one or more electrodes such as electrodes of the IDT 16 may be deposited on a top surface of the layered substrate 30 at step 1004. After depositing the electrodes, an embedding layer such as the embedding layer 24 may be deposited substantially over the electrodes and the layered substrate 30 at step 1006. Finally, the additional material such as the overlaying layer 26 may be deposited overtop the embedding layer 24 at step 1008. One or more of the deposition steps may be performed by any means or method including, but not limited to, lamination, spraying, etching, etc. and may include the use of one or more of a photoresist layer, a solder-resist layer, or some other layer. In some instances, the overlaying layer 26 includes the same material as the fast substrate 28, and another die may be stacked overtop the overlaying layer 26. That is, a second PBAW device may be stacked overtop the PBAW device 50 or the PBAW device 800.

In accordance with one or more embodiments, a piezoelectric boundary acoustic wave (PBAW) device is provided. The PBAW includes a substrate; a piezoelectric film on the substrate; an interdigital transducer on the piezoelectric film, the interdigital transducer having electrodes arranged with an electrode period; and an overcoat layer on the piezoelectric film, the electrodes of the interdigital transducer being embedded in the overcoat layer, a thickness of the overcoat layer being larger than twice the electrode period.

In one or more embodiments, the substrate has a shear velocity faster than 4000 m/s. In one or more embodiments, the substrate is made of a material selected from silicon, quartz, silicon carbide, or sapphire. In one or more embodiments, the electrodes are embedded in the piezoelectric film.

In one or more embodiments, the PBAW further includes one or more material layers disposed between the substrate and the piezoelectric film. In one or more embodiments, the PBAW further includes a dielectric film disposed between the substrate and the piezoelectric film. In one or more embodiments, the dielectric film is made of silicon oxide.

In one or more embodiments, the substrate is a semiconductor substrate with a trap-rich band. In one or more embodiments, the thickness of the overcoat layer is larger than three times the electrode period. In one or more embodiments, the thickness of the overcoat layer is larger than four times the electrode period.

In one or more embodiments, the PBAW device is free of a cavity directly above the interdigital transducer.

In one or more embodiments, the overcoat layer includes an embedding layer on the piezoelectric film, the electrodes of the interdigital transducer being embedded in the embedding layer; and an overlaying layer on the embedding layer, a thickness of the overlaying layer being larger than twice the electrode period. In one or more embodiments, the embedding layer is made of silicon oxide. In one or more embodiments, the overlaying layer is made of a material selected from aluminum nitride, silicon nitride, aluminum oxide, silicon, silicon carbide, or diamond.

In one or more embodiments, the piezoelectric film is made of lithium tantalate or lithium niobate. In one or more embodiments, a thickness of the piezoelectric film is thinner than the electrode period. In one or more embodiments, the piezoelectric film is made of a Y-rotated, X-propagating lithium niobate with an orientation between Y and Y+50°. In one or more embodiments, the piezoelectric film is made of a Y-rotated, X-propagating lithium niobate with an orientation between Y+115° and Y+130°.

In one or more embodiments, another die is stacked atop the overcoat layer. In one or more embodiments, the overcoat layer has a same material as the substrate, and the another die is a second PBAW stacked atop the PBAW.

In accordance with one or more embodiments, a method of forming a piezoelectric boundary acoustic wave (PBAW) device is provided. The method includes forming a layered substrate, the layered substrate including a substrate and a piezoelectric film on the substrate, a shear wave velocity of the substrate being larger than that of the piezoelectric film; forming interdigital transducer on the piezoelectric film; forming a dielectric layer coating the interdigital transducer; and depositing an overlaying layer on the dielectric layer, a shear wave velocity of the overlaying layer being larger than that of the dielectric layer.

In one or more embodiments, the piezoelectric film is obtained by wafer bonding and polishing. In one or more embodiments, the piezoelectric film is obtained by implanting ions on a piezoelectric wafer, bonding the piezoelectric wafer on a substrate wafer, splitting the piezoelectric wafer to form an initial piezoelectric film, and polishing the initial piezoelectric film. In one or more embodiments, the forming of the layered substrate includes forming a trap-rich layer in a top portion of the substrate. In one or more embodiments, the forming of the layered substrate includes forming an intermediary dielectric layer between the substrate and the piezoelectric film. In one or more embodiments, the overlaying layer is made by bonding a wafer on top of the embedding layer.

In accordance with one or more embodiments, a wireless device comprising a boundary acoustic wave device is provided. The boundary acoustic wave device includes a substrate; a piezoelectric film on the substrate; an interdigital transducer on the piezoelectric film, the interdigital transducer having electrodes arranged with an electrode period; and an overcoat layer on the piezoelectric film, the electrodes of the interdigital transducer being embedded in the overcoat layer, wherein the PBAW device is free from a cavity directly above the interdigital transducer.

In one or more embodiments, a thickness of the overcoat layer is larger than twice the electrode period. In one or more embodiments, the substrate has a shear velocity faster than 4000 m/s. In one or more embodiments, the substrate is made of a material selected from silicon, quartz, silicon carbide, or sapphire. In one or more embodiments, the electrodes are embedded in the piezoelectric film.

In one or more embodiments, the PBAW further includes one or more material layers disposed between the substrate and the piezoelectric film. In one or more embodiments, the PBAW further includes a dielectric film disposed between the substrate and the piezoelectric film. In one or more embodiments, the dielectric film is made of silicon oxide.

In one or more embodiments, the substrate is a semiconductor substrate with a trap-rich band. In one or more embodiments, the thickness of the overcoat layer is larger than three times the electrode period. In one or more embodiments, the thickness of the overcoat layer is larger than four times the electrode period.

In one or more embodiments, the PBAW device is free of a cavity directly above the interdigital transducer.

In one or more embodiments, the overcoat layer includes an embedding layer on the piezoelectric film, the electrodes of the interdigital transducer being embedded in the embedding layer; and an overlaying layer on the embedding layer, a thickness of the overlaying layer being larger than twice the electrode period. In one or more embodiments, the embedding layer is made of silicon oxide. In one or more embodiments, the overlaying layer is made of a material selected from aluminum nitride, silicon nitride, aluminum oxide, silicon, silicon carbide, or diamond.

In one or more embodiments, the piezoelectric film is made of lithium tantalate or lithium niobate. In one or more embodiments, a thickness of the piezoelectric film is thinner than the electrode period. In one or more embodiments, the piezoelectric film is made of a Y-rotated, X-propagating lithium niobate with an orientation between Y and Y+50°. In one or more embodiments, the piezoelectric film is made of a Y-rotated, X-propagating lithium niobate with an orientation between Y+115° and Y+130°.

In one or more embodiments, another die is stacked atop the overcoat layer. In one or more embodiments, the overcoat layer has a same material as the substrate, and the another die is a second PBAW stacked atop the PBAW.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A piezoelectric boundary acoustic wave (PBAW) device, comprising:
a substrate;
a piezoelectric film on the substrate;
an interdigital transducer on the piezoelectric film, the interdigital transducer having electrodes arranged with an electrode period; and
an overcoat layer on the piezoelectric film, the electrodes of the interdigital transducer being embedded in the overcoat layer, a thickness of the overcoat layer being larger than twice the electrode period.

2. The PBAW device of claim 1, wherein the substrate has a shear velocity faster than 4000 m/s.

3. The PBAW device of claim 1, wherein the electrodes are embedded in the piezoelectric film.

4. The PBAW device of claim 1, further comprising:
one or more material layers disposed between the substrate and the piezoelectric film; or
a dielectric film disposed between the substrate and the piezoelectric film.

5. The PBAW device of claim 1, wherein the substrate is a semiconductor substrate with a trap-rich band.

6. The PBAW device of claim 1, wherein the PBAW device is free of a cavity directly above the interdigital transducer.

7. The PBAW device of claim 1, wherein the overcoat layer includes:
an embedding layer on the piezoelectric film, the electrodes of the interdigital transducer being embedded in the embedding layer; and
an overlaying layer on the embedding layer, a thickness of the overlaying layer being larger than twice the electrode period.

8. The PBAW device of claim 1, wherein the piezoelectric film is made of a Y-rotated, X-propagating lithium niobate with an orientation between Y and Y+50°.

9. A method of forming a piezoelectric boundary acoustic wave (PBAW) device, comprising:
forming a layered substrate, the layered substrate including a substrate and a piezoelectric film on the substrate, a shear wave velocity of the substrate being larger than that of the piezoelectric film;
forming interdigital transducer on the piezoelectric film;
forming a dielectric layer coating the interdigital transducer; and
depositing an overlaying layer on the dielectric layer, a shear wave velocity of the overlaying layer being larger than that of the dielectric layer.

10. The method of claim 9, wherein the piezoelectric film is obtained by wafer bonding and polishing.

11. The method of claim 9, wherein the piezoelectric film is obtained by implanting ions on a piezoelectric wafer, bonding the piezoelectric wafer on a substrate wafer, splitting the piezoelectric wafer to form an initial piezoelectric film, and polishing the initial piezoelectric film.

12. The method of claim 9, wherein the forming of the layered substrate includes forming a trap-rich layer in a top portion of the substrate.

13. The method of claim 9, wherein the forming of the layered substrate includes forming an intermediary dielectric layer between the substrate and the piezoelectric film.

14. The method of claim 9, wherein the overlaying layer is made by bonding a wafer on top of the embedding layer.

15. A wireless device, comprising:
a boundary acoustic wave device, comprising:
a substrate;
a piezoelectric film on the substrate;
an interdigital transducer on the piezoelectric film, the interdigital transducer having electrodes arranged with an electrode period; and
an overcoat layer on the piezoelectric film, the electrodes of the interdigital transducer being embedded in the overcoat layer, wherein the PBAW device is free from a cavity directly above the interdigital transducer.

16. The wireless device of claim 15, wherein a thickness of the overcoat layer is larger than twice the electrode period.

17. The wireless device of claim 15, wherein the boundary acoustic wave device further comprises:
one or more material layers disposed between the substrate and the piezoelectric film; or
a dielectric film disposed between the substrate and the piezoelectric film.

18. The wireless device of claim 15, wherein the substrate is a semiconductor substrate with a trap-rich band.

19. The wireless device of claim 15, wherein the overcoat layer includes:
an embedding layer on the piezoelectric film, the electrodes of the interdigital transducer being embedded in the embedding layer; and
an overlaying layer on the embedding layer, a thickness of the overlaying layer being larger than twice the electrode period.

20. The wireless device of claim 15, wherein the piezoelectric film is made of a Y-rotated, X-propagating lithium niobate with an orientation between Y and Y+50°.
